(19) United States
(12) Patent Application Publication
(10) Pub. No.: US 2018/0082944 A1
(43) Pub. Date: Mar. 22, 2018

(54) SEMICONDUCTOR DEVICE AND ITS MANUFACTURING METHOD

(71) Applicant: RENESAS ELECTRONICS CORPORATION, Tokyo (JP)

(72) Inventor: Shinichi MAEDA, Ibaraki (JP)

(21) Appl. No.: 15/704,669

(22) Filed: Sep. 14, 2017

(30) Foreign Application Priority Data
Sep. 21, 2016 (JP) 2016-183899

(51) Int. Cl. H01L 23/522; H01L 49/02; H01L 21/02; H01L 21/768

(52) U.S. Cl. CPC H01L 23/5223; H01L 28/60; H01L 21/76877; H01L 21/0217; H01L 21/02164

(57) ABSTRACT

In a semiconductor device having a capacitive element, an increase in a leak current caused by the generation of a parasitic MOSFET is avoided by thinning the insulating film between the electrodes of the capacitive element and thickening the interlayer insulating film. The semiconductor device is provided with a capacitive element including a lower electrode formed on the main surface of the semiconductor substrate in the capacitive element region and an upper electrode formed just above the lower electrode through the silicon nitride film and an interlayer insulating film including a silicon oxide film, a silicon nitride film, and a silicon oxide film over the semiconductor substrate in a region different from the capacitive element region.

### CROSS-REFERENCE TO RELATED APPLICATIONS

The disclosure of Japanese Patent Application No. 2016-183899 filed on Sep. 21, 2016 including the specification, drawings and abstract is incorporated herein by reference in its entirety.

### BACKGROUND

The invention relates to a semiconductor device and its manufacturing method, and, for example, it is preferably applied to a semiconductor device having a capacitive element including a nitride film as an insulating film between electrodes, the nitride film forming a part of an interlayer insulating film in another region.

It is known that a laminated film including a first silicon oxide film, a silicon nitride film, and a second silicon oxide film sequentially formed on the main surface of a semiconductor substrate is used as an interlayer insulating film in a contact layer and that the silicon nitride film is used as an insulating film between electrodes of the capacitive element in another region.

Further, when electrically separating the mutually adjacent semiconductor elements formed on the main surface of the semiconductor substrate, there is a method of not forming an insulating film embedded in the main surface of a semiconductor substrate between the semiconductor elements. Specifically, there is a method of making the main surface of the semiconductor substrate between the semiconductor elements in a non-doped state without dopant, or a method of forming the semiconductor elements and forming a semiconductor region of a second conductivity type different from a first conductivity type or a semiconductor region of the first conductivity type, between the semiconductor regions (electrodes) of the first conductivity type mutually adjacent on the main surface of the semiconductor substrate.

Japanese Unexamined Patent Application Publication No. 2009-152445 describes that a laminated film including a first silicon oxide film, a silicon nitride film, and a second silicon oxide film sequentially formed on the main surface of a semiconductor substrate is used as an interlayer insulating film of a contact layer and as an insulating film of a capacitive element.

### SUMMARY

When using the silicon nitride film that is a part of the interlayer insulating film as the insulating film between the electrodes of the capacitive element, the upper electrode of the capacitive element and a wiring on the interlayer insulating film are formed in order to come into contact with the top surface of the silicon nitride film. However, in order to stabilize the capacity characteristic of the capacitive element having the semiconductor substrate as a lower electrode, the insulating film between the electrodes of the capacitive element has to be formed thinner; on the contrary, in order to avoid forming a parasitic MOSFET having the interlayer insulating film as a gate insulating film, the interlayer insulating film has to be formed thicker.

When a part of the interlayer insulating film and a part of the insulating film between the electrodes of the capacitive element are formed by a common film and the insulating film between the electrodes of the capacitive element is formed thinner, there is such a problem as to deteriorate a reliability in the semiconductor device according to the operation of the parasitic Metal Oxide Semiconductor Field Effect Transistor (MOSFET) unless the interlayer insulating film is formed thicker.

When a metal film formed on the silicon nitride film is processed to separately form the upper electrode of the capacitive element and the other wirings, there is a fear that the silicon nitride film under the metal film may be eliminated in this processing. In this case, there arises a problem that a contaminant flows into the semiconductor substrate through the silicon oxide film under the silicon nitride film.

Other objects and novel characteristics will be apparent from the description of the specification and the attached drawings.

The outline of the typical one of the embodiments disclosed in the specification will be briefly described as follows.

A semiconductor device according to an embodiment has an interlayer insulating film including a first silicon oxide film, a silicon nitride film, and a second silicon oxide film sequentially formed on a semiconductor substrate and a capacitive element including a lower electrode formed on the main surface of the semiconductor substrate and an upper electrode formed above the lower electrode through a third silicon oxide film in contact with the silicon nitride film and the top surface of the silicon nitride film.

A method of manufacturing a semiconductor device according to another embodiment includes a step of forming a silicon nitride film and a third silicon oxide film on the first silicon oxide film on the semiconductor substrate in the first region and on the second silicon oxide film on the semiconductor substrate in the second region, hence to eliminate the second silicon oxide film in the second region to bare the top surface of the silicon nitride film. Thereafter, by processing the conductive film formed on the semiconductor substrate, wirings on the third silicon oxide film in the first region and the upper electrode on the silicon nitride film in the second region are formed.

According to the embodiment, a reliability of a semiconductor device can be improved.

### BRIEF DESCRIPTION OF THE DRAWINGS

FIG. 1 is a top plan view of a semiconductor device according to an embodiment of the invention.

FIG. 2 is a cross-sectional view taken along the line A-A of FIG. 1.

FIG. 3 is a top plan view and cross-sectional view of the semiconductor device according to the embodiment of the invention.

FIG. 4 is a cross-sectional view of the semiconductor device according to the embodiment in the manufacturing process.

FIG. 5 is a cross-sectional view of the semiconductor device in the manufacturing process following FIG. 4.

FIG. 6 is a cross-sectional view of the semiconductor device in the manufacturing process following FIG. 5.

FIG. 7 is a cross-sectional view of the semiconductor device in the manufacturing process following FIG. 6.

FIG. 8 is a cross-sectional view of the semiconductor device in the manufacturing process following FIG. 7.

FIG. 9 is a cross-sectional view of the semiconductor device in the manufacturing process following FIG. 8.

FIG. 10 is a cross-sectional view of the semiconductor device in the manufacturing process following FIG. 9.

FIG. 11 is a cross-sectional view of the semiconductor device in the manufacturing process following FIG. 10.

FIG. 12 is a cross-sectional view of the semiconductor device in the manufacturing process following FIG. 11.

FIG. 13 is a cross-sectional view of the semiconductor device in the manufacturing process following FIG. 12.

FIG. 14 is a graph showing a relation between time and leak current.

FIG. 15 is a cross-sectional view of a semiconductor device according to a modified example of the embodiment of the invention.

FIG. 16 is a cross-sectional view of a semiconductor device in the manufacturing process as a comparison example.

FIG. 17 is a cross-sectional view of the semiconductor device in the manufacturing process following FIG. 16.

FIG. 18 is a cross-sectional view of the semiconductor device in the manufacturing process following FIG. 17.

FIG. 19 is a cross-sectional view of a semiconductor device as a comparison example.

### DETAILED DESCRIPTION

The following embodiments will be described divided into a plurality of sections or forms if necessary for the sake of convenience; unless otherwise specified, they are mutually related to each other and one is related to the other in a part or in the whole of the modified examples as the details and supplementary description. Further, in the following embodiments, when referring to the number of the elements (including piece, numeric value, amount, and range), the number is not restricted to the referred number but may be more or less than the specified number, unless particularly specified and unless restricted to the specified number apparently on the principle. Further, in the following embodiments, it is needless to say that the component elements (including operation step) are not always essential unless particularly specified and unless apparently considered compulsory on the principle. Similarly, in the following embodiments, when referring to the shape and the positional relation of the component elements, they are to include their similarity or approximation unless particularly specified and unless they have apparently different shape and positional relation on the principle. This is true to the above numeric value and range.

Hereinafter, the embodiments will be described in detail based on the drawings. In all the drawings for describing the embodiments, the same reference numerals are attached to the materials having the same functions and the description thereof is not repeated. In the following embodiments, the description of the same or similar portions is not repeated principally unless necessary.

### <Structure of Semiconductor Device>

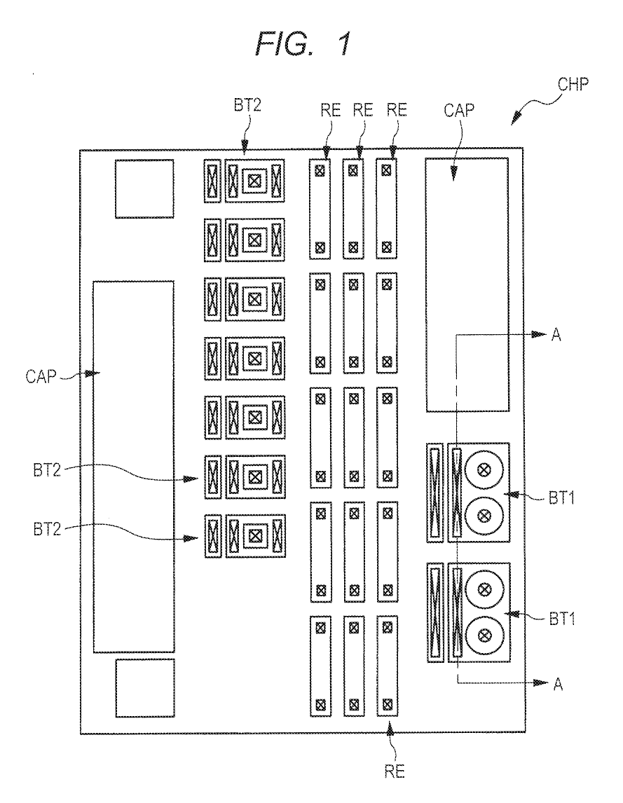

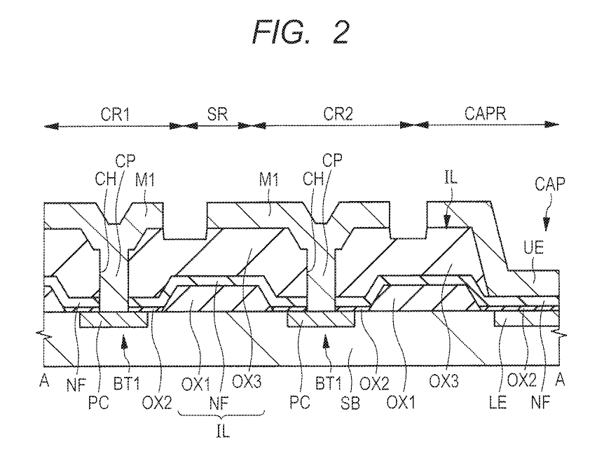

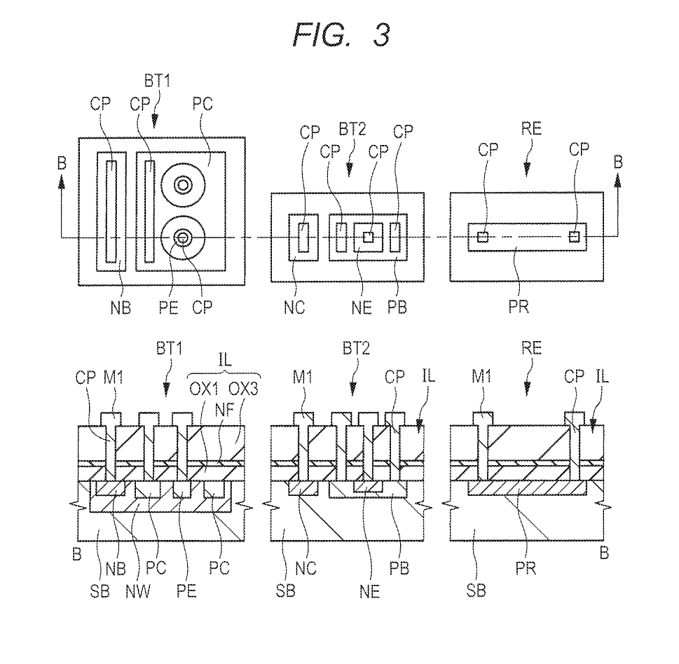

At first, the structure of a semiconductor device in the embodiment will be described. FIG. 1 is a top plan view showing the structure of a semiconductor chip as the semiconductor device according to the embodiment. FIG. 2 is a cross-sectional view showing the structure of the semiconductor device according to the embodiment. FIG. 2 is a cross-sectional view taken along the line A-A of FIG. 1. FIG. 3 is a view showing plan layout and cross-section of elements forming the semiconductor device according to the embodiment. FIG. 3 shows a PNP-type bipolar transistor, an NPN-type bipolar transistor, and a resistor element in the order from the left.

As shown in FIG. 1, a semiconductor chip CHP in the embodiment includes a semiconductor substrate (semiconductor wafer) SB (refer to FIG. 2), a plurality of capacitive elements CAP, PNP-type bipolar transistors BT1, NPN-type bipolar transistors BT2, and resistor elements RE mounted on the semiconductor substrate in a mixed way. The capacitive elements CAP, the PNP-type bipolar transistors BT1, the NPN-type bipolar transistors BT2, and the resistor elements RE are semiconductor elements and these semiconductor elements are arranged on the semiconductor substrate respectively in plural. The semiconductor elements arranged on the semiconductor substrate in plural are isolated from each other at a distance.

FIG. 2 shows p-type semiconductor regions PC forming the respective collector electrodes of the two PNP-type bipolar transistors BT1 as the mutually adjacent semiconductor elements. The semiconductor regions PC are formed on the top surface of the semiconductor substrate SB. In FIG. 2, of the two PNP-type bipolar transistors BT1, the p-type semiconductor region PC that is the collector electrode forming one PNP-type bipolar transistor BT1 is shown in the connection region CR1 and the p-type semiconductor region PC that is the collector electrode forming the other PNP-type bipolar transistor BT1 is shown in the connection region CR2. The connection regions CR1 and CR2 are the regions to couple the contact plugs (connection portions) CP for supplying a collector potential to the semiconductor regions PC, to the top surfaces thereof.

The semiconductor substrate SB is a non-doped single crystal silicon substrate with no dopant introduced. The semiconductor substrate SB may be a substrate including a single crystal silicon substrate and an epitaxial growth layer formed on the single crystal silicon layer. In this case, for example, the single crystal silicon substrate is a boron-doped p-type substrate and the epitaxial growth layer thereon is a layer including no dopant. Regardless of the presence of the epitaxial growth layer, the plane orientation (crystal orientation) on the main surface of the semiconductor substrate SB is (100).

FIG. 2 shows the connection region CR1, the inter-element region SR, the connection region CR2, and the capacitive element region CAPR in the order from the left. The inter-element region SR is a space between the mutually adjacent semiconductor regions PC, or a space between the mutually adjacent semiconductor elements (for example, PNP-type bipolar transistors BT1), to electrically separate the semiconductor elements. The capacitive element region CAPR is a region having the capacitive element CAP including a lower electrode LE formed by an n-type semiconductor region on the main surface of the semiconductor substrate SB and an upper electrode UE made of a metal film formed above the lower electrode LE on the main surface of the semiconductor substrate SB through a silicon oxide film OX2 and a silicon nitride film NF. The lower electrode LE is a region with the n-type dopant (for example, phosphorus (P)) introduced on the main surface of the semiconductor substrate SB.

The laminated film including the silicon oxide film OX2 and the silicon nitride film NF in the capacitive element region CAPR is an insulating film provided in order to isolate the lower electrode LE from the upper electrode UE in the capacitive element CAP. According to this, the insulating film for isolating the lower electrode LE from the upper electrode UE has an Oxide Nitride (ON) structure. The whole bottom surface of the upper electrode UE forming the capacitive element CAP is in contact with the top surface of the silicon nitride film NF. In other words, any silicon oxide film does not intervene between the upper electrode UE and the silicon nitride film NF. The capacity in the capacitive element CAP is generated between the lower electrode LE and the upper electrode UE mutually facing each other through the laminated film.

Here, a part of the upper electrode UE is formed from the region having no silicon oxide film OX3 just above the lower electrode LE to the region just above the interlayer insulating film IL including the silicon oxide film OX3; however, the upper electrode UE does not have to be formed on the silicon oxide film OX3. The upper electrode UE a part of which covers the silicon oxide film OX3 can be regarded as the wiring electrically coupled to the upper electrode UE forming the capacitive element CAP.

The film thickness of the silicon oxide film OX2 is, for example, 3 to 10 nm. The film thickness of the silicon nitride film NF is, for example, 100 nm. The film thickness of the upper electrode UE is, for example, 1 μm.

The silicon nitride film NF forms a part of the interlayer insulating film IL, in the region other than the capacitive element region CAPR, or in the connection regions CR1 and CR2 and the inter-element region SR. Specifically, in the connection regions CR1 and CR2 and the inter-element region SR, the interlayer insulating film IL made of a laminated film including the silicon oxide film OX1, the silicon nitride film NF, and the silicon oxide film OX3 formed in the order from the main surface of the semiconductor substrate SB is formed on the semiconductor substrate SB and the semiconductor regions PC. In other words, in the capacitive element region CAPR, the interlayer insulating film IL including the silicon oxide films OX1 and OX3 is not formed. The interlayer insulating film IL formed by the laminated film including the silicon oxide film OX1, the silicon nitride film NF, and the silicon oxide film OX3 forms an Oxide Nitride Oxide (ONO) film.

In the connection regions CR1 and CR2, the interlayer insulating film IL in the vicinity of each contact plug CP does not include the silicon oxide film OX1 but includes the silicon oxide film OX2, the silicon nitride film NF, and the silicon oxide film OX3 sequentially formed on the main surface of the semiconductor substrate SB. Specifically, the interlayer insulating film IL includes the mutually adjacent silicon oxide films OX1 and OX2, the silicon nitride film NF, and the silicon oxide film OX3. The contact plug CP is not in contact with the silicon oxide film OX1 but penetrates the silicon oxide film OX2 and also penetrates the silicon oxide film OX1 staying away from the contact plug CP.

The film thickness (thickness) of the interlayer insulating film IL referred in this specification means the thickness of the interlayer insulating film IL including the silicon oxide film OX1, the silicon nitride film NF, and the silicon oxide film OX3 in the inter-element region SR and the connection regions CR1 and CR2 in a direction vertical to the main surface of the semiconductor substrate SB, unless specifically described. Because, it is mainly in the inter-element region SR that a parasitic MOSFET occurs and a leak current flows and a distance between the main surface of the semiconductor substrate SB in the inter-element region SR and the wiring M1 working as the gate electrode of the parasitic MOSFET affects the generation of the leak current caused by the operation of the parasitic MOSFET.

For example, in the bottom of an isolation groove between the adjacent wirings M1, a concave portion is formed on the top surface of the silicon oxide film OX3; however, the film thickness (thickness) of the interlayer insulating film IL referred in this specification indicates the maximum thickness of the interlayer insulating film IL including the silicon oxide film OX1, the silicon nitride film NF, and the silicon oxide film OX3 in the region where the above concave portion is not formed, unless particularly described. Because the region where the isolation groove and the concave portion are formed does not include any wiring M1 working as the gate electrode of the parasitic MOSFET, where the thickness of the interlayer insulating film IL hardly affects the operation of the parasitic MOSFET.

The film thickness of the silicon oxide film OX1 is 500 to 1000 nm, and specifically, for example, 1000 nm. The silicon oxide film OX1 and the silicon oxide film OX2 are both aligned between the silicon nitride film NF and the semiconductor substrate SB and the film thickness of the silicon oxide film OX1 is much larger than that of the silicon oxide film OX2. The film thickness of the silicon oxide film OX3 is, for example, 300 to 2000 nm. As an example, the concrete film thickness of the silicon oxide film OX3 is defined as 1000 nm. In other words, the silicon oxide film OX3 is larger than any of the silicon oxide film OX2 and the silicon nitride film NF in the film thickness.

The interlayer insulating film IL is a layer with the contact plug CP penetrating from the top surface to the bottom surface, and the interlayer insulating film IL and a plurality of contact plugs CP form a contact layer. Each contact plug CP is embedded in a contact hole (connection hole) CH penetrating the interlayer insulating film IL from the top surface to the bottom surface.

The wirings M1 made of a metal film are formed on the interlayer insulating film IL in the connection regions CR1 and CR2 and the inter-element region SR. The wiring M1 is coupled to the contact plug CP integrally. In short, the wiring M1 and the contact plug CP are made of one metal film. The wiring M1 and the contact plug CP is a conductive film mainly made of, for example, an aluminum (AL) film.

Further, the upper electrode UE has the same film thickness as the wiring M1, mainly made of aluminum (AL), similarly to the wiring M1 and the contact plug CP. This is because the upper electrode UE and the wiring M1 are made of a film obtained by separating one metal film made in the manufacturing process of a semiconductor device, in short, made of the same layered film. A part of the wirings M1 may be mutually coupled to the upper electrode UE integrally. Each film thickness of the wiring M1 and the upper electrode UE is, for example, 1 μm.

The silicon oxide film OX2 and the silicon nitride film NF are much thinner compared with the film thickness of the silicon oxide films OX1 and OX3, the wiring M1, and the upper electrode UE. These thinner silicon oxide film OX2 and silicon nitride film NF are used as the insulating film between the electrodes of the capacitive element CAP, hence to be able to increase the capacity of the capacitive element CAP and stabilize the capacity characteristic of the capacitive element CAP.

Isolation grooves for separating the metal film forming the wiring M1 and the upper electrode UE are formed respectively between the mutually adjacent wirings M1 and between the wiring M1 and the upper electrode UE adjacent to each other. The top surface of the silicon oxide film OX3 is bared on the bottom surface of the isolation groove. Further, the silicon nitride film NF is not bared on the side wall and the bottom surface of the isolation groove. In other words, the top surface of the silicon nitride film NF is covered with the silicon oxide film OX3 just under the isolation groove.

Further, in the bottom of the isolation groove, a concave portion is formed on the top surface of the silicon oxide film OX3 and the concave portion ranges from the top surface of the silicon oxide film OX3 to a midway depth of the silicon oxide film OX3. In other words, also just under the concave portion, the top surface of the silicon nitride film NF is covered with the silicon oxide film OX3. Each concave portion is formed on the top surface of the silicon oxide film OX3 between the adjacent wirings M1 and between the wiring M1 and the upper electrode UE adjacent to each other, or on the top surface of the silicon oxide film OX3 bared from the wiring M1 and the upper electrode UE.

Here, an element isolation region made of an insulating film for separating the elements from each other is not formed in the inter-element region SR. In other words, there is no groove with the insulating film embedded therein on the main surface of the semiconductor substrate SB in the inter-element region SR and the elements (for example, PNP-type bipolar transistor BT1) are separated from each other by the semiconductor substrate SB without any dopant introduced in the inter-element region SR.

In the semiconductor substrate SB, the semiconductor region PC is considered to be covered with the n-type semiconductor region (for example, the semiconductor region NW shown in FIG. 3); in FIG. 2, however, the n-type semiconductor region is not illustrated and the n-type dopant is not introduced on the main surface of the semiconductor substrate SB in the inter-element region SR. Even when the n-type or p-type dopant is introduced on the main surface of the semiconductor substrate SB in the inter-element region SR, their amount is very small, which can be neglected as not being introduced.

FIG. 3 is a top plan view and cross-sectional view of each of the PNP-type bipolar transistor BT1, the NPN-type bipolar transistor BT2, and the resistance element RE as an example of the semiconductor elements formed near the top surface of the semiconductor substrate SB. The lower figure shows each cross-sectional view taken along the line B-B of each top plan view shown in the upper side. FIG. 3 shows the cross-section more briefly than FIG. 2. Particularly, the interlayer insulating film IL shown in FIG. 3 has the silicon oxide film OX2 in the vicinity of the contact plug CP, similarly to the interlayer insulating film IL shown in FIG. 2; in the cross-sectional view of FIG. 3, the silicon oxide film OX2 is not illustrated. Further, in the cross-sectional view of FIG. 3, in the region adjacent to the wiring M1, the concave portion formed on the top surface of the silicon oxide film OX3 is not illustrated.

As shown in FIG. 3, the PNP-type bipolar transistor BT1 includes an n-type semiconductor region NB as the base electrode formed on the main surface of the semiconductor substrate SB, a p-type semiconductor region PC as the collector electrode formed on the main surface of the semiconductor substrate SB, and a p-type semiconductor region PE as the emitter electrode formed on the main surface of the semiconductor substrate SB. Further, on the main surface of the semiconductor substrate SB, the n-type semiconductor region NW formed deeper than any of the semiconductor regions NB, PC, and PE with the lower dopant concentration than the semiconductor region NB is formed to cover the semiconductor regions NB, PC, and PE. The semiconductor region NW is electrically coupled to the semiconductor region NB and a part of the semiconductor region NW is located on the main surface of the semiconductor substrate SB between the semiconductor region PC and the semiconductor region PE.

Further, the NPN-type bipolar transistor BT2 includes an n-type semiconductor region NC as the collector electrode formed on the main surface of the semiconductor substrate SB, a p-type semiconductor region PB as the base electrode formed on the main surface of the semiconductor substrate SB, and an n-type semiconductor region NE as the emitter electrode formed on the main surface of the semiconductor substrate SB. In the semiconductor substrate SB, the semiconductor region NE is covered with the semiconductor region PB and on the main surface of the semiconductor substrate SB, a part of the semiconductor region PB is located between the semiconductor region NC and the semiconductor region NE.

Although it is not illustrated, also on the main surface of the semiconductor substrate SB where the NPN-type bipolar transistor BT2 is formed, the n-type semiconductor region having lower dopant concentration to cover the semiconductor regions PB, NE, and NC may be formed in the same way as the semiconductor region NW.

The resistance element RE is formed by the p-type semiconductor region PR formed on the main surface of the semiconductor substrate SB. The semiconductor region PR extends in the direction along the main surface of the semiconductor substrate SB and the contact plugs CP are coupled to the top surface at the both ends. All the above mentioned n-type semiconductor regions have the n-type dopant (for example, phosphorus (P)) introduced on the main surface of the semiconductor substrate SB, and all the above mentioned p-type semiconductor regions have the p-type dopant (for example, boron (B)) introduced on the main surface of the semiconductor substrate SB.

The interlayer insulating film IL as an ONO film made by a laminated film including the silicon oxide film OX1, the silicon nitride film NF, and the silicon oxide film OX3 sequentially formed on the main surface of the semiconductor substrate SB is formed just above the semiconductor substrate SB where the PNP-type bipolar transistor BT1, the NPN-type bipolar transistor BT2, and the resistance element RE are formed. Above the semiconductor substrate SB, a plurality of contact plugs CP penetrating the interlayer insulating film IL are formed and the wirings M1 are respectively formed on the contact plugs CP.

The wiring M1 and the contact plug CP are integrally formed of, for example, mainly an aluminum (AL) film. The contact plugs CP are respectively coupled to the top surfaces of the semiconductor regions NC, PB, NE, NB, PC, and PE. A silicide layer made of, for example, cobalt silicide (CoSi) may be formed between the respective top surfaces of the semiconductor regions NC, PB, NE, NB, PC, PE, and PR and the contact plugs CP.

The film thickness of these contact plugs CP and the thickness of the interlayer insulating film IL around the contact plugs CP are larger than the film thickness of the laminated film including the silicon oxide film OX2 and the silicon nitride film NF in the capacitive element region CAPR shown in FIG. 2.

### <Effect of Semiconductor Device>

Hereinafter, the effects of the semiconductor device according to the embodiment will be described using a comparison example shown in FIG. 19. FIG. 19 is a cross-sectional view of a semiconductor device according to the comparison example, showing the connection region CR1, the inter-element region SR, the connection region CR2, and the capacitive element region CAPR correspondingly to FIG. 2.

When a plurality of semiconductor elements are formed on the main surface of the semiconductor substrate or the main surface of the epitaxial growth layer and the element isolation region made of an insulating film is not formed between the elements, the wiring on the interlayer insulating film works as the gate electrode and a parasitic MOSFET occasionally occurs. In other words, for example, the two semiconductor regions forming mutually different elements, formed on the main surface of the semiconductor substrate, work as the source and drain regions of the parasitic MOSFET and a leak current may flow mutually between the two semiconductor regions.

In other words, when trying to electrically separating the semiconductor elements adjacent to each other on the main surface of the semiconductor substrate without forming any insulating film embedded in the main surface of the semiconductor substrate, the wiring on the interlayer insulating film works as the gate electrode and the interlayer insulating film works as the gate insulating film; an inversion layer is formed on the main surface of the semiconductor substrate between the semiconductor regions respectively forming the semiconductor elements and there is a fear of a leak current flowing. Thus, the parasitic MOSFET is formed and the leak current flows, hence to cause an abnormal operation in the semiconductor device.

Further, in order to separate the elements, a semiconductor region for separation may be formed on the main surface of the semiconductor substrate between the elements. Also in this case, the semiconductor region for separation and the semiconductor region for forming the element work as the source and drain regions; as the result, a leak current may flow in the parasitic MOSFET.

In these cases, there occurs such a problem that the semiconductor elements do not operate normally or such a problem as to increase the power consumption for running a desired current to the semiconductor elements. The above problem becomes more remarkable when the plane orientation (crystal orientation) on the main surface of the semiconductor substrate is (100) than when the plane orientation is (111). Because the interface level of the substrate main surface is lower when the plane orientation is (100) than when the plane orientation is (111), which causes the threshold voltage of the parasitic MOSFET having the main surface of the semiconductor substrate as a channel region to decrease. When the diameter of a semiconductor wafer is comparatively large, for example, 8 inches, the wafers having the plane orientation (100) on the main surface of the semiconductor substrate are mainly manufactured and the wafer having the plane orientation (100) can be manufactured at a lower cost than the wafer having the plane orientation (111).

Therefore, when using a low-priced wafer having a large diameter, the plane orientation of the semiconductor substrate can be (100), and in this case, it is particularly important to avoid the generation of the parasitic MOSFET. In order to avoid the generation of the parasitic MOSFET, the film thickness of the interlayer insulating film on the semiconductor substrate should be increased, hence to increase a distance between the wiring working as the gate electrode and the main surface of the semiconductor substrate working as the channel region. Increase of the interlayer insulating film means increase of the gate insulating film of the parasitic MOSFET; therefore, it is possible to avoid the generation of the parasitic MOSFET and the generation of the leak current caused by passing current to the parasitic MOSFET.

Here, when the capacitive element having the lower electrode as a part of the main surface of the semiconductor substrate and the upper electrode formed on the lower electrode through the insulating film is formed on the semiconductor substrate, the conductive film in the same layer as the wiring may form the upper electrode and a part of the insulating film forming the interlayer insulating film may be used as the insulating film between the upper and lower electrodes. However, when the interlayer insulating film thickened in order to avoid the generation of the parasitic MOSFET as mentioned above is used as the insulating film between the electrodes of the capacitive element as it is, the capacity of the capacitive element decreases and further the capacity characteristic of the capacitive element gets unstable. Like the semiconductor device of the comparison example shown in FIG. 19, the silicon nitride film forming the interlayer insulating film is used as the insulating film between the electrodes of the capacitive element, another insulating film forming the interlayer insulating film may be eliminated in the forming region of the capacitive element.

As shown in FIG. 19, the semiconductor substrate SB includes the connection region CR1, the inter-element region SR, the connection region CR2, and the capacitive element region CAPR, similarly to the embodiment shown in FIG. 2. The structure inside the semiconductor substrate SB in the connection region CR1, the inter-element region SR, the connection region CR2, and the capacitive element region CAPR and the structure of the capacitive element CAP, the PNP-type bipolar transistor BT1, the NPN-type bipolar transistor BT2, and the resistance element (not illustrated) are the same as those of the semiconductor device according to the embodiment. In short, the capacitive element CAP includes the lower electrode LE, the upper electrode UE, and the laminated insulating film including the silicon oxide film OX2 and the silicon nitride film NF between the electrodes.

The interlayer insulating film IL1 including the silicon oxide film OX1 and the silicon nitride film NF is formed on the semiconductor substrate SB in the connection region CR1, the inter-element region SR, and the connection region CR2. The wiring M1 is in contact with the top surface of the interlayer insulating film IL1, specifically the top surface of the silicon nitride film NF. In short, the semiconductor device of the comparison example is different from the semiconductor device of the embodiment mainly in that the interlayer insulating film IL1 in the region other than the capacitive element region CAPR does not have the insulating film (the silicon oxide film OX3 shown in FIG. 2) on the silicon nitride film NF.

As mentioned above, the reason why only the laminated insulating film including the thinner silicon oxide film OX2 and silicon nitride film NF forms the space between the electrodes of the capacitive element CAP is because avoiding increase and fluctuation in the film thickness of the insulating film between the electrodes increases the capacity of the capacitive element CAP and avoids fluctuation in the capacity characteristic of the capacitive element CAP.

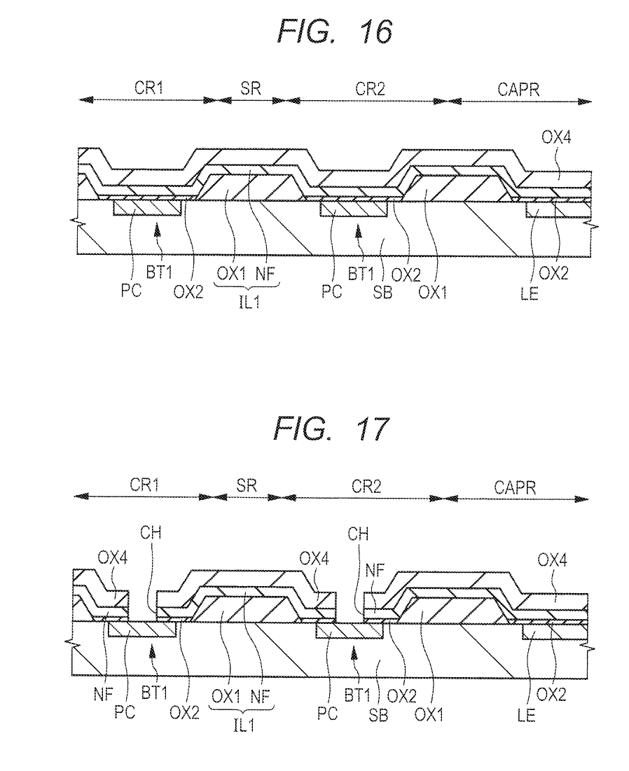

In the comparison example, the reason why the interlayer insulating film IL1 does not include the silicon oxide film on the silicon nitride film NF is because the whole silicon oxide film formed on the silicon nitride film NF is eliminated in the manufacturing process of the semiconductor device in order to thin the insulating film between the electrodes of the capacitive element CAP, as described later by using FIGS. 16 to 19. Therefore, both the upper electrode UE and the wiring M1 of the comparison example shown in FIG. 19 are in direct contact with the top surface of the silicon nitride film NF.

When the upper electrode UE and the plural wirings M1 are separated from each other and an isolation groove penetrating the metal film is formed, the silicon nitride film NF under the metal film is also processed together by processing the above metal film in direct contact with the top surface of the silicon nitride film NF and a part of the top surface of the silicon oxide film OX1 is bared in the bottom of the isolation groove. Although the silicon nitride film NF works as a protective film for avoiding the dopant (contaminant) such as movable ions from intruding into the semiconductor substrate SB and the silicon oxide film OX1, once the silicon nitride film NF is eliminated from the bottom of the isolation groove, there arises such a problem as to deteriorate the function as the protective film of the silicon nitride film NF.

In this case, since the dopant intrudes into the semiconductor substrate SB through the silicon oxide film OX1 just under the isolation groove, for example, there arises such a problem as to fluctuate the threshold voltage of the field-effect transistor (FET) formed in the semiconductor substrate SB or such a problem as to increase a leak current between the elements. In short, the reliability of the semiconductor device is deteriorated.

In the comparison example, the insulating film on the silicon nitride film NF is eliminated so as not to interposing the insulating film between the silicon nitride film NF of the capacitive element region CAPR and the upper electrode UE, and in accordance with this, the insulating film on the silicon nitride film NF in the region other than the capacitive element region CAPR is also eliminated. Therefore, the interlayer insulating film IL1 is formed only on the silicon oxide film OX1 and the silicon nitride film NF. In this case, it is hard to thicken the interlayer insulating film IL1. Also, it is hard to avoid the generation of the parasitic MOSFET and the generation of the leak current. Accordingly, the reliability of the semiconductor device is deteriorated. Here, the wiring M1 on the interlayer insulating film IL1 in the inter-element region SR works as the gate electrode of the parasitic MOSFET, and the respective semiconductor regions PC in the connection regions CR1 and CR2 work as the source and drain regions, hence to operate the parasitic MOSFET.

On the contrary, in the semiconductor device according to the embodiment, the interlayer insulating film IL in the region other than the capacitive element region CAPR is formed by the silicon oxide film OX1, the silicon nitride film NF, and the silicon oxide film OX3 sequentially formed on the main surface of the semiconductor substrate SB, hence to thicken the interlayer insulating film IL. In the capacitive element region CAPR, the insulating film between the electrodes of the capacitive element CAP is formed by only the silicon oxide film OX2 and the silicon nitride film NF; since the above insulating film does not include the silicon oxide film OX3, the insulating film between the electrodes of the capacitive element CAP can be thinned and further fluctuation in the film thickness of the insulating film can be avoided. Therefore, deterioration in the capacity of the capacitive element CAP can be avoided and further, the capacitive element CAP of a desired capacity characteristic can be formed stably.

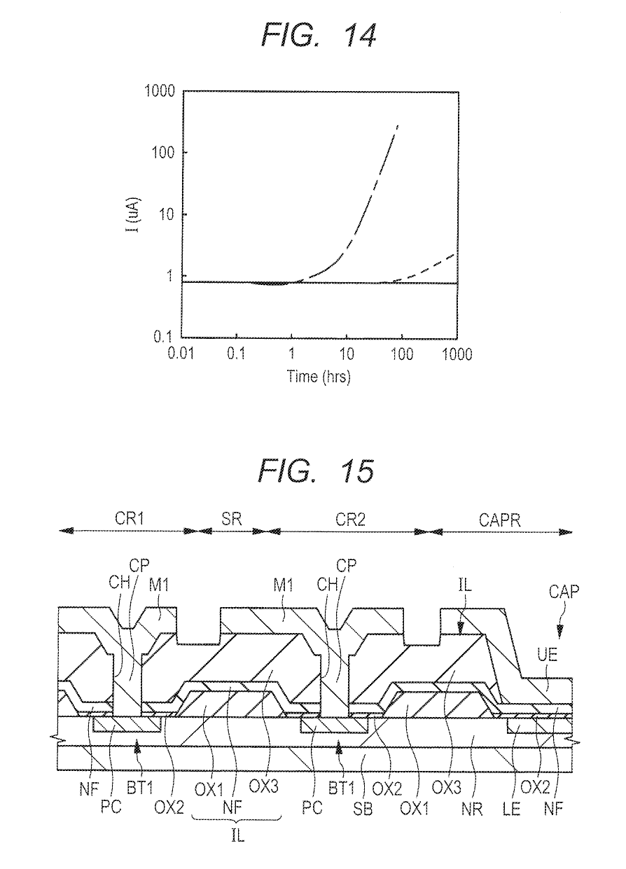

The effect of the thickened interlayer insulating film IL will be described according to FIG. 14. FIG. 14 is a graph indicating a relation between the elapse of time and the leak current value when the thicknesses of the insulating film (for example, silicon oxide film OX3) between the silicon nitride film NF and the wiring M1 shown in FIG. 2 are 0 nm, 300 nm, and 1000 nm. The horizontal axis of the graph indicates the time and the vertical axis indicates the leak current. The time means the continuous period of a stress test to operate the semiconductor device on a trial basis with a predetermined voltage continuously applied to each semiconductor element. In FIG. 14, an alternate long and short dash line indicates when the film thickness of the insulating film on the silicon nitride film NF is 0 nm, in short, in the case of the comparison example shown in FIG. 19; a short dashed line indicates when the film thickness is 300 nm; and a solid line indicates when the film thickness is 1000 nm.

When the operation time of the semiconductor device passes a predetermine period, according to the graph shown in FIG. 14, it is found that the leak current starts increasing in the semiconductor device when the film thickness of the insulating film on the silicon nitride film NF is 0 nm. On the contrary, when the film thickness is 300 nm and 1000 nm, it takes much more time for the leak current to start increasing, than when the film thickness is 0 nm. In the embodiment, since the silicon oxide film OX3 on the silicon nitride film NF shown in FIG. 2 is formed with the film thickness of, for example, 300 to 2000 nm, it is possible to avoid the generation of the parasitic MOSFET. Accordingly, it is possible to avoid the generation of the leak current caused by the operation of the parasitic MOSFET.

In short, the interlayer insulating film IL1 in the comparison example shown in FIG. 19 includes only the silicon oxide film OX1 and the silicon nitride film NF, while the interlayer insulating film IL shown in FIG. 2 includes the thick silicon oxide film OX3, in addition to the silicon oxide film OX1 and the silicon nitride film NF. Accordingly, the film thickness of the interlayer insulating film IL according to the embodiment is larger than that of the interlayer insulating film IL1 in the comparison example. In the embodiment, the interlayer insulating film IL positioned between the gate electrode and the channel region of the parasitic MOSFET can be thickened, hence to avoid the generation of the parasitic MOSFET and to suppress the leak current caused by the operation of the parasitic MOSFET. Therefore, the reliability of the semiconductor device can be improved.

As shown in FIG. 2, in the embodiment, the silicon oxide film OX3 covers the silicon nitride film NF, and therefore, even when the isolation grooves for separating the upper electrode UE and the plural wirings M1 are formed, it is possible to avoid eliminating the silicon nitride film NF. Since the function of the silicon nitride film NF as the protective film is not damaged, the dopant (contaminant) can be avoided from intruding to the semiconductor substrate SB from the bottom of the isolation groove through the silicon oxide film OX1. Therefore, it is possible to avoid deterioration of the semiconductor device caused by the dopant, hence to improve the reliability of the semiconductor device.

Since the leak current caused by the operation of the parasitic MOSFET is larger when the plane orientation on the main surface of the semiconductor substrate SB is (100) than when it is (111), the effect of the semiconductor device in the embodiment is more effectively obtained when the plane orientation is (100).

By avoiding the generation of the leak current or by increasing a leak margin between the elements, the voltage supplied to the elements can be increased, and by shortening the interval between the semiconductor regions PC or the interval between the semiconductor elements, the semiconductor device can be miniaturized.

### <Manufacturing Method of Semiconductor Device>

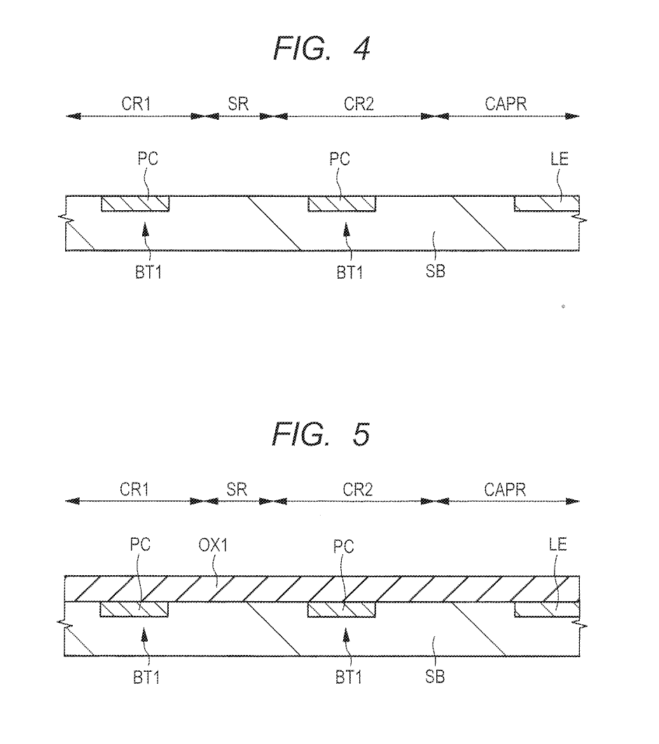

Hereinafter, a method of manufacturing a semiconductor device according to the embodiment will be described using FIGS. 4 to 12. FIGS. 4 to 12 are cross-sectional views of the semiconductor device according to the embodiment in the manufacturing processes. Similarly to FIG. 2, each of FIGS. 4 to 12 shows the connection region CR1, the inter-element region SR, the connection region CR2, and the capacitive element region CAPR in the order from the left.

As shown in FIG. 4, a semiconductor substrate SB made of single crystal silicon is prepared. The semiconductor substrate SB has a main surface and a rear surface opposite to the main surface, and the plane orientation of the main surface is (100).

Then, by implanting the p-type dopant (for example, boron (B)) in the main surface of the semiconductor substrate SB in the respective connection regions CR1 and CR2 according to the photolithography and the ion implantation, a plurality of semiconductor regions PC as the p-type dopant regions are formed. Further, by implanting the n-type dopant (for example, phosphorus (P)) in the main surface of the semiconductor substrate SB in the capacitive element region CAPR according to the photolithography and the ion implantation, the lower electrode LE as the n-type dopant region is formed. Here, by selectively performing the ion implantation in the other regions, the semiconductor regions NC, NE, NB, PC, PE, PR, and NW shown in FIG. 3 are formed. According to this, the PNP-type bipolar transistor BT1, and the NPN-type bipolar transistor BT2, and the resistance element RE shown in FIG. 3 are formed.

As shown in FIG. 5, by performing the oxidation treatment on the main surface of the semiconductor substrate SB, the silicon oxide film OX1 is formed on the main surface of the semiconductor substrate SB. The film thickness of the silicon oxide film OX1 is 500 to 1000 nm; specifically, for example, 1000 nm. The silicon oxide film OX1 can be formed, for example, according to the thermal oxidation.

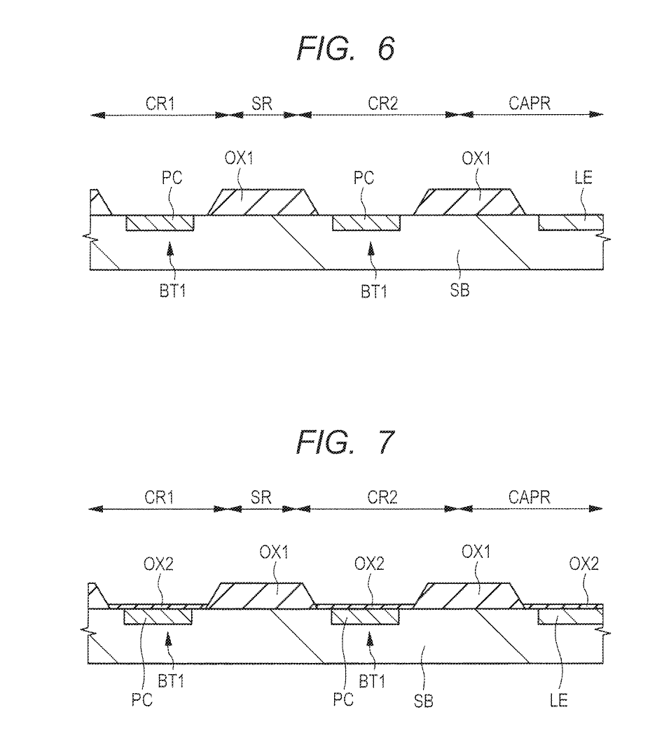

Then, as shown in FIG. 6, according to the photolithography and the etching, a part of the silicon oxide film OX1 is eliminated in the capacitive element region CAPR and the connection regions CR1 and CR2; according to this, the main surface of the semiconductor substrate SB is bared. In this etching process, for example, dry etching and wet etching are used in combination. In each of the connection regions CR1 and CR2, a portion to eliminate the silicon oxide film OX1 is the portion where the contact plug will be formed later. In the capacitive element region CAPR, a portion to eliminate the silicon oxide film OX1 is the portion just above the lower electrode LE, which will overlap with the upper electrode formed later in plan view.

As shown in FIG. 7, the silicon oxide film OX2 to cover the main surface of the semiconductor substrate SB bared from the silicon oxide film OX1 is formed by performing the thermal oxidation. The film thickness of the silicon oxide film OX2 is smaller than that of the silicon oxide film OX1. The film thickness of the silicon oxide film OX2 is, for example, 3 to 10 nm.

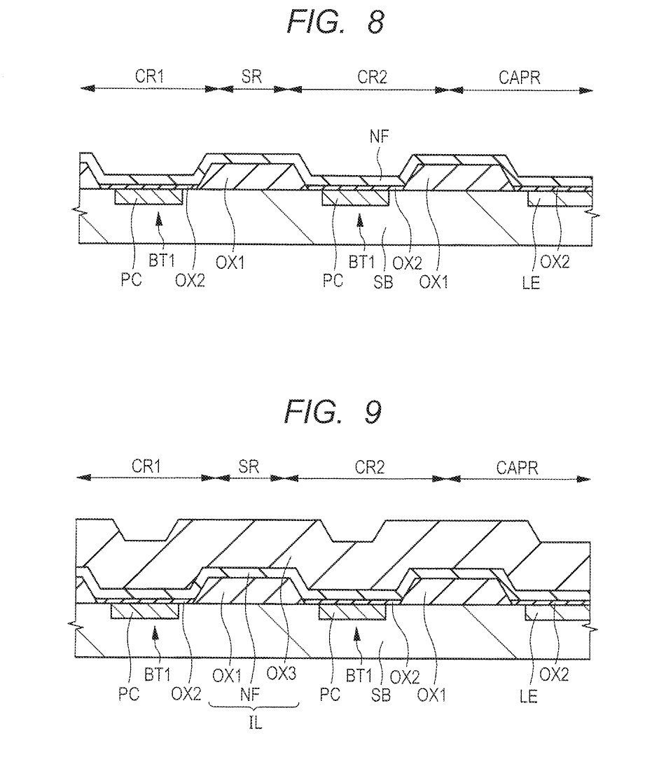

Then, as shown in FIG. 8, the silicon nitride film NF is formed on the semiconductor substrate SB and the silicon oxide films OX1 and OX2, for example, according to the Chemical Vapor Deposition (CVD). The film thickness of the silicon nitride film NF is, for example, 100 nm. According to this, all the surfaces of the silicon oxide films OX1 and OX2 are covered with the silicon nitride film NF. The silicon nitride film NF is made of, for example, Low Pressure (LP)-SiN film.

Next, as shown in FIG. 9, the thick silicon oxide film OX3 is formed on the silicon nitride film NF, for example, according to the CVD. The film thickness of the silicon oxide film OX3 is larger than that of the silicon nitride film NF. The film thickness of the silicon oxide film OX3 is, for example, 300 to 2000 nm. According to this, the whole top surface of the silicon nitride film NF is covered with the silicon oxide film OX3. The laminated film including the silicon oxide film OX1, the silicon nitride film NF, and the silicon oxide film OX3 forms the interlayer insulating film IL. The silicon oxide film OX3 is made of, for example, Low Pressure-Plasma Tetra Ethyl Ortho Silicate (LP-PTEOS) film.

The reason why the minimum limit of the film thickness of the silicon oxide film OX3 is defined as 300 nm is because the generation of the leak current can be effectively suppressed with the film thickness of the silicon oxide film OX3 300 nm and more, as shown in FIG. 14. The reason why the maximum limit of the film thickness of the silicon oxide film OX3 is defined as 2000 nm is because when the film thickness of the silicon oxide film OX3 is more than 2000 nm, it takes much longer time to process the silicon oxide film OX3. The reason why the maximum limit of the film thickness of the silicon oxide film OX3 is defined as 2000 nm is because the contact hole penetrating the silicon oxide film OX3 has a taper and when the film thickness of the silicon oxide film OX3 is more than 2000 nm, it makes the layout of the contact plug restrictive, which disturbs the miniaturization of the semiconductor device.

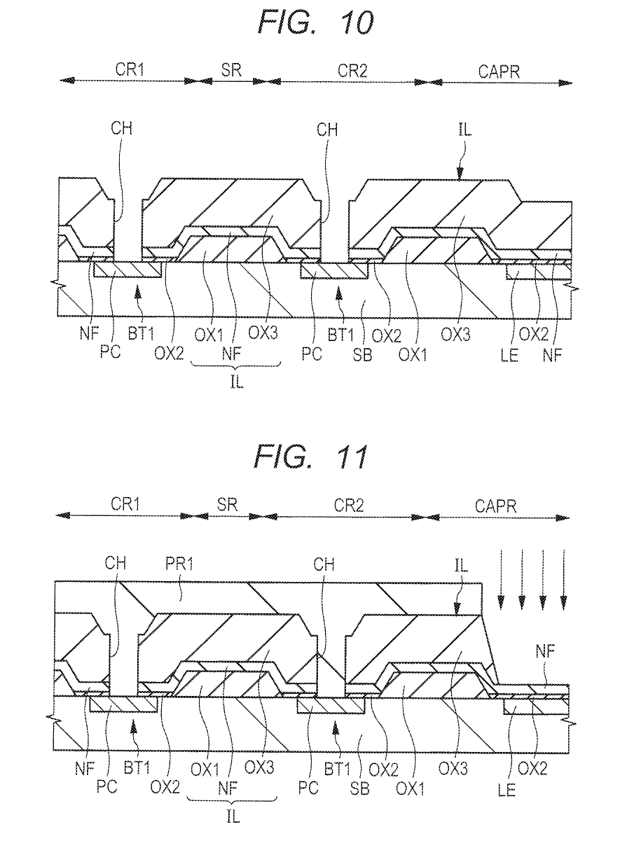

As shown in FIG. 10, the contact holes CH penetrating the interlayer insulating film IL are formed in the connection regions CR1 and CR2, according to the photolithography and the wet etching. The contact holes CH in the connection regions CR1 and CR2 are respectively formed just above the semiconductor regions PC and the top surfaces of the semiconductor regions PC are respectively bared from the interlayer insulating film IL in the bottoms of the contact holes CH.

As shown in FIG. 11, a resist pattern made of a photoresist film PR1 to cover the interlayer insulating film IL is formed above the main surface of the semiconductor substrate SB. The photoresist film PR1 is a pattern to cover the contact holes CH and the interlayer insulating film IL in the connection regions CR1 and CR2 and the inter-element region SR and to bare the top surface of the silicon oxide film OX3 just above the lower electrode LE in the capacitive element region CAPR.

Then, the silicon oxide film OX3 in the capacitive element region CAPR is eliminated according to the wet etching with the photoresist film PR1 used as the etching mask. According to this, the silicon oxide film OX3 is bored to bare the top surface of the silicon nitride film NF just above the lower electrode LE. The process of selectively eliminating the silicon oxide film OX3 in the capacitive element region CAPR as mentioned above is the main characteristic point in the manufacturing method of the semiconductor device according to the embodiment.

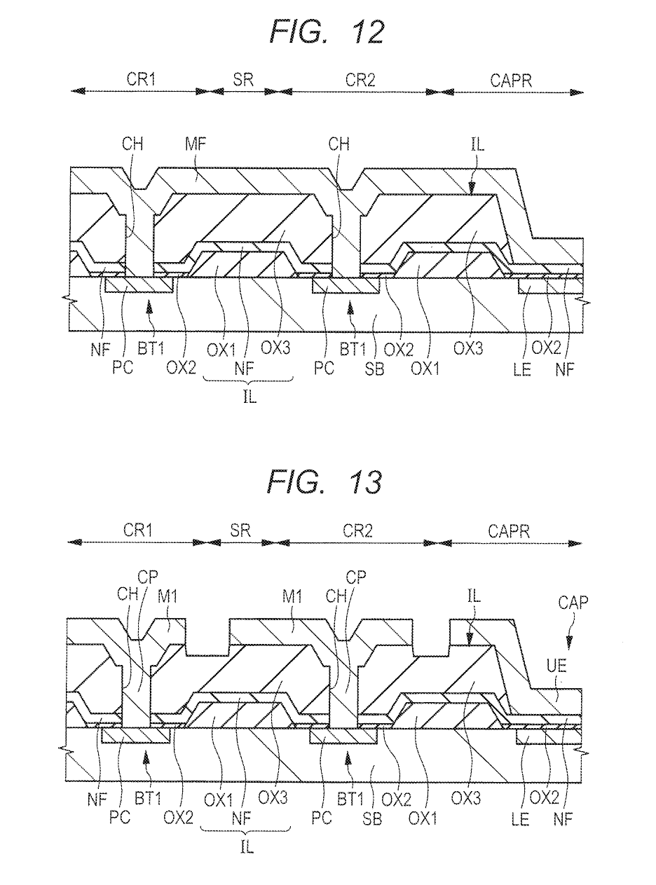

As shown in FIG. 12, after eliminating the photoresist film PR1, the metal film MF is formed on the whole main surface of the semiconductor substrate SB, for example, according to the sputtering. The metal film MF is mainly formed of, for example, an aluminum (Al) film. The metal film MF is formed by a laminated film including, for example, a thin barrier conductive film and a main conductive film made of an aluminum film and the barrier conductive film is made of, for example, a titanium (Ti) film, a tantalum (Ta) film or their nitride film. The metal film MF is completely embedded in each contact hole CH. The metal film MF covers the top surface of the interlayer insulating film IL in the connection regions CR1 and CR2 and the inter-element region SR and covers the top surface of the silicon nitride film NF in the capacitive element region CAPR.

As shown in FIG. 13, the metal film MF is processed according to the photolithography and the dry etching, thereby forming the contact plugs CP made of the metal film MF, the wirings M1 made of the metal film MF, and the upper electrode UE made of the metal film MF. Here, by eliminating a part of the metal film MF, the isolation grooves ranging from the top surface of the metal film MF to the top surface of the interlayer insulating film IL, specifically to the top surface of the silicon oxide film OX3, are formed, hence to form the contact plugs CP, the wirings M1, and the upper electrode UE.

The wiring M1 is a conductive film formed on the top surface of the interlayer insulating film IL in the connection regions CR1 and CR2 and the inter-element region SR. The contact plugs CP are connection portions to be embedded respectively in a plurality of contact holes CH. The upper electrode UE is formed just above the lower electrode LE and only the laminated film including the silicon oxide film OX2 and the silicon nitride film NF intervenes between the upper electrode UE and the lower electrode LE. The upper electrode UE and the lower electrode LE form the capacitive element CAP. The upper electrode UE may be integrated with some of the wirings M1 or may be separated from all the wirings M1.

The top surface of the silicon oxide film OX3 forming the interlayer insulating film IL is bared in the bottom of the isolation groove between the adjacent wirings M1 and in the bottom of the isolation groove between the wiring M1 and the upper electrode UE adjacent to each other. The silicon oxide film OX3 has a large film thickness of, for example, 1000 nm. Therefore, even when the etching is performed for a time more than necessity in order to separate the metal film MF assuredly by the isolation groove, the isolation groove never arrives at the silicon nitride film NF. In other words, in the over-etching, a concave portion is formed on the top surface of the silicon oxide film OX3 in the bottom of the isolation groove, but the concave portion never arrives at the silicon nitride film NF, so that the silicon nitride film NF is not bared.

According to the above processes, the semiconductor device according to the embodiment is substantially completed.

### <Effect of Manufacturing Method of Semiconductor Device>

Hereinafter, the effect of the manufacturing method of the semiconductor device according to the embodiment will be described by comparison with the semiconductor device in the comparison example shown in FIGS. 16 to 19. FIGS. 16 to 18 are cross-sectional views of the semiconductor device according to the comparison example in the manufacturing processes. Each of FIGS. 16 to 19 shows the connection region CR1, the inter-element region SR, the connection region CR2, and the capacitive element region CAPR in the order from the left, similarly to FIG. 2.

In the manufacturing process of the semiconductor device in the comparison example, the same processes having been described according to FIGS. 4 to 8 are performed. According to this, various kinds of semiconductor elements are formed in the semiconductor substrate SB, and the silicon oxide films OX1 and OX2 and the silicon nitride film NF are formed on the main surface of the semiconductor substrate SB. According to this, the interlayer insulating film IL1 made by the laminated film including the silicon oxide film OX1 and the silicon nitride film NF is formed (refer to FIG. 16) in the connection regions CR1 and CR2 and the inter-element region SR.

As shown in FIG. 16, a silicon oxide film OX4 is formed on the top surface of the silicon nitride film NF, for example, according to the CVD. The film thickness of the silicon oxide film OX4 is less than, for example, 300 nm and smaller than the film thickness of the silicon oxide film OX3 (refer to FIG. 9). The silicon oxide film OX4 is made of, for example, LP-TEOS film. The silicon oxide film OX4 is a film all to be removed later and not a film forming the interlayer insulating film IL1. The silicon oxide film OX4 is a film to protect the silicon nitride film NF in the manufacturing process of the semiconductor device.

Then, as shown in FIG. 17, a plurality of holes penetrating the laminated film including the interlayer insulating film IL1 and the silicon oxide film OX4 in the connection regions CR1 and CR2 are formed according to the photolithography and the wet etching. According to this, a plurality of the contact holes CH penetrating the interlayer insulating film IL1 are formed. Here, through the etching process for forming the contact holes CH, the top surface of the silicon nitride film NF in the capacitive element region CAPR is covered with the silicon oxide film OX4.

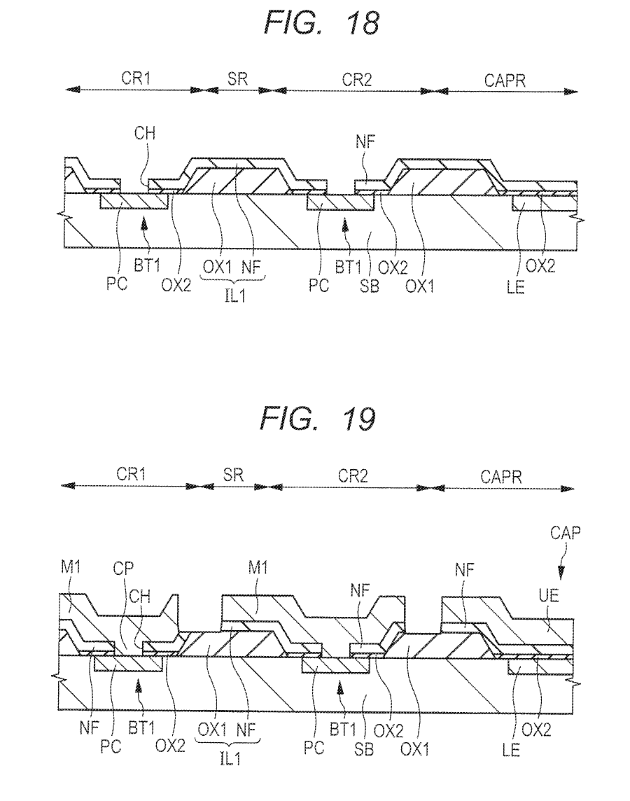

As shown in FIG. 18, all the silicon oxide film OX4 above the semiconductor substrate SB is eliminated according to the wet etching, hence to bare the top surface of the silicon nitride film NF. Here, since the insulating film between the elements of the capacitive element formed later is formed only by the silicon oxide film OX2 and the silicon nitride film NF, the silicon oxide film OX4 in the entire region including the capacitive element region CAPR is eliminated.

By performing the same processes having been described according to FIGS. 12 and 13, the semiconductor device in the comparison example shown in FIG. 19 is substantially completed. Specifically, after the metal film is formed on the silicon nitride film NF and the main surface of the semiconductor substrate SB including the contact holes CH, the metal film is processed, hence to form the wirings M1 and the upper electrode UE. According to this, the capacitive element CAP including the upper electrode UE and the lower electrode LE is formed in the capacitive element region CAPR. Further, the contact plugs CP are formed within the contact holes CH.

The isolation grooves penetrating the metal film are formed in order to separate the adjacent wirings M1 and the wiring M1 and the upper electrode UE adjacent to each other. In order to make the isolation groove assuredly penetrate the metal film, the dry etching process in forming the isolation groove is performed with much more time than the necessity to eliminate the film thickness of the metal film. According to this, over etching happens and a part of the silicon nitride film NF as the base of the metal film is eliminated. Therefore, in the bottom of the isolation groove, the silicon nitride film NF is eliminated to bare the top surface of the silicon oxide film OX1.

In this case, the function as the protective film of the silicon nitride film NF is damaged in the process of the cleaning performed after the above processing of the metal film. Therefore, dopant (contaminant) such as movable ions intrudes into the semiconductor substrate SB through the silicon oxide film OX1 bared in the bottom of the isolation groove, hence to deteriorate the semiconductor device. In short, there arises, for example, such a problem as to fluctuate the threshold voltage of the field-effect transistor (FET) formed in the semiconductor substrate SB or such a problem as to increase the leak current between the elements. As the result, there occurs a problem of deteriorating the reliability of the semiconductor device.

On the other hand, compared with the comparison example, the process having been described according to FIG. 11, specifically, the process of selectively eliminating the silicon oxide film OX3 in the capacitive element region CAPR is added in the manufacturing method of the semiconductor device according to the embodiment. According to this, the silicon oxide film OX3 is left in the connection region CR1 and the inter-element region SR, and the silicon oxide film OX3 is eliminated in the capacitive element region CAPR, hence to thicken the interlayer insulating film IL and thin the insulating film between the electrodes of the capacitive element.

In the capacitive element region CAPR, the insulating film between the electrodes of the capacitive element CAP is formed by only the silicon oxide film OX2 and the silicon nitride film NF, and it does not include the silicon oxide film OX3; therefore, it is possible to avoid decreasing the capacity of the capacitive element CAP and further to form the capacitive element CAP having a desired capacity characteristic stably. As having been described according to FIG. 14, the interlayer insulating film IL positioned between the gate electrode and the channel region of the parasitic MOSFET can be thickened (refer to FIG. 13); therefore, the parasitic MOSFET can be avoided and the leak current caused by the operation of the parasitic MOSFET can be suppressed. As the result, the reliability of the semiconductor device can be improved.

Further, as shown in FIG. 13, in the embodiment, since the silicon oxide film OX3 covers the silicon nitride film NF, even when the isolation grooves to separate the upper electrode UE and the plural wirings M1 are formed, the silicon nitride film NF can be avoided from being eliminated. Therefore, the function of the silicon nitride film NF as a protective film is not damaged, and the dopant (contaminant) can be avoided from intruding into the semiconductor substrate SB from the bottom of the isolation groove through the silicon oxide film OX1. As the result, it is possible to avoid deterioration of the semiconductor device caused by the dopant and accordingly, to improve the reliability of the semiconductor device.

Since the leak current caused by the operation of the parasitic MOSFET gets larger when the plane orientation on the main surface of the semiconductor substrate SB is (100) than when it is (111), the effect of the semiconductor device according to the embodiment can be obtained more when the plane orientation is (100).

By avoiding the generation of the leak current or by increasing the inter-element leak margin, for example, the voltage supplied to the elements can be increased, or by reducing the intervals between the semiconductor regions PC, that is, the intervals between the semiconductor elements, the semiconductor device can be miniaturized.

### Modified Example

Hereinafter, a modified example of the semiconductor device and its manufacturing method according to the embodiment will be described by using FIG. 15. FIG. 15 is a cross-sectional view showing the semiconductor device of the modified example of the embodiment. FIG. 15 shows the cross section at the same position as in FIG. 2. The modified example is different from the semiconductor device having been described according to FIGS. 2 to 13 only in that in order to isolate the semiconductor regions formed on the main surface of the semiconductor substrate SB, a semiconductor region having a conductivity type different from that of the above semiconductor region is formed on the main surface of the semiconductor substrate SB and there is no difference in the other components.

As shown in FIG. 15, the semiconductor device of the modified example has the same structure as that shown in FIG. 2 and further, it includes a semiconductor region NR on the main surface of the semiconductor substrate SB. The semiconductor region NR is an n-type semiconductor region formed from the main surface of the semiconductor substrate SB to a midway depth of the semiconductor substrate SB, where the n-type dopant (for example, phosphorus (P)) is introduced. The semiconductor region NR is formed in the process having been described using FIG. 4, for example, according to the ion implantation. The ion implantation process may be performed at any time as far as it is after the preparation of the semiconductor substrate SB and before the process of forming the silicon oxide film OX1 having been described according to FIG. 5.

The semiconductor region NR is formed deeper than any of the semiconductor regions NC, PB, NE, NB, PC, PE, and PR shown in FIG. 3. The semiconductor region NR has the conductivity type (n-type) different from the conductivity type (p-type) of the semiconductor region PC shown in FIG. 15. Therefore, the mutually adjacent semiconductor regions PC are isolated by the semiconductor region NR therebetween.

In order to avoid the leak current flowing between the adjacent semiconductor regions PC, also in the modified example, it is important to thicken the interlayer insulating film IL on the semiconductor substrate SB between the adjacent semiconductor regions PC. According to the embodiment, the silicon oxide film OX3 in the capacitive element region CAPR is eliminated to thin the insulating film between the electrodes and the silicon oxide film OX3 is left as a film forming the interlayer insulating film IL, hence to increase the film thickness of the interlayer insulating film IL. As the result, the generation of the parasitic MOSFET can be avoided and the same effect as the semiconductor device and its manufacturing method having been described using FIGS. 1 to 13 can be obtained.

As set forth hereinabove, although the invention made by the inventor et al. has been described based on the embodiments, it is needless to say that the invention is not restricted to the embodiments, but various modifications can be made without departing from its spirit.

What is claimed is:

1. A semiconductor device comprising:
a semiconductor substrate including a first region, a second region, a third region, and a fourth region over a main surface thereof;
a first semiconductor region of a first conductivity type formed over the main surface of the semiconductor substrate in the first region;
a second semiconductor region of the first conductivity type formed over the main surface of the semiconductor substrate in the second region;
a lower electrode formed over the main surface of the semiconductor substrate in the third region;
an upper electrode formed over the lower electrode through a second silicon oxide film and a silicon nitride film, in contact with a top surface of the silicon nitride film;
an interlayer insulating film including a first silicon oxide film, the silicon nitride film, and a third silicon oxide film sequentially formed over the main surface of the semiconductor substrate in the fourth region between the first region and the second region; and
a wiring formed over the interlayer insulating film in the fourth region,
wherein the lower electrode and the upper electrode form a capacitive element.

2. The device according to claim 1,
wherein a concave portion is formed in a top surface of the interlayer insulating film bared from the wiring, and
wherein a top surface of the silicon nitride film just under the concave portion is covered with the third silicon oxide film.

3. The device according to claim 1,
wherein no silicon oxide film is formed between the upper electrode and the silicon nitride film.

4. The device according to claim 1,
wherein plane orientation of the main surface of the semiconductor substrate is (100).

5. The device according to claim 1,
wherein film thickness of the first silicon oxide film is larger than the film thickness of the second silicon oxide film.

6. The device according to claim 1, further comprising:
a first connection portion electrically coupled to the first semiconductor region, through penetrating the interlayer insulating film; and
a second connection portion electrically coupled to the first semiconductor region, through penetrating the interlayer insulating film,
wherein the first semiconductor region forms a first semiconductor element and the second semiconductor region forms a second semiconductor element.

7. The device according to claim 1, further comprising
a third semiconductor region of a second conductivity type different from the first conductivity type, formed over the main surface of the semiconductor substrate in the fourth region.

8. The device according to claim 1,
wherein the wiring and the upper electrode are formed of same layered film.

9. A method of manufacturing a semiconductor device comprising the steps of:
(a) preparing a semiconductor substrate including a first region, a second region, a third region, and a fourth region over a main surface thereof;
(b) forming a first semiconductor region of a first conductivity type over the main surface of the semiconductor substrate in the first region, forming a second semiconductor region of the first conductivity type over the main surface of the semiconductor substrate in the second region, and forming a lower electrode over the main surface of the semiconductor substrate in the third region;
(c) after the step (b), forming a first silicon oxide film over the main surface of the semiconductor substrate to bare the main surface of the semiconductor substrate in the third region;
(d) after the step (b), forming a second silicon oxide film having a smaller film thickness than the first silicon oxide film, to cover the main surface of the semiconductor substrate in the third region;
(e) sequentially forming a silicon nitride film and a third silicon oxide film to cover the first silicon oxide film and the second silicon oxide film;
(f) eliminating a part of the third silicon oxide film to bare a top surface of the silicon nitride film in the third region;
(g) forming a conductive film over an interlayer insulating film including the first silicon oxide film, the silicon nitride film, and the third silicon oxide film formed in the first region, the second region, and the fourth region and over the silicon nitride film in the third region; and
(h) forming an upper electrode made of the conductive film just above the lower electrode and a plurality of wirings made of the conductive film over the interlayer insulating film, by processing the conductive film,
wherein the lower electrode and the upper electrode form a capacitive element, and
wherein a part of the wirings is formed over the interlayer insulating film in the fourth region positioned between the first region and the second region.

10. The method according to claim 9,
wherein in the step (h), the wirings and the upper electrode at a distance from each other are formed by forming an isolation groove for separating the conductive film, and
wherein just under the isolation groove, a top surface of the silicon nitride film is covered with the third silicon oxide film.

11. The method according to claim 9,
wherein in the step (g), the conductive film to cover a top surface of the interlayer insulating film in contact with the top surface of the silicon nitride film.

12. The method according to claim 9,
wherein plane orientation over the main surface of the semiconductor substrate is (100).

13. The method according to claim 9,
wherein film thickness of the first silicon oxide film is larger than the film thickness of the second silicon oxide film.

14. The method according to claim 9 further comprising the step of
(f1) after the step (f), forming a first connection hole penetrating the interlayer insulating film, to bare a top surface of the first semiconductor region from the interlayer insulating film and a second connection hole penetrating the interlayer insulating film, to bare a top surface of the second semiconductor region from the interlayer insulating film,
wherein in the step (g), the conductive film fills the first connection hole and the second connection hole, and
wherein the first semiconductor region forms a first semiconductor element and the second semiconductor region forms a second semiconductor element.

15. The method according to claim 9, further comprising
(b1) before the step (c), forming a third semiconductor region of a second conductivity type different from the first conductivity type over the main surface of the semiconductor substrate in the fourth region.
